(19) United States
(12) Patent Application Publication
(10) Pub. No.: US 2007/0272153 A1
(43) Pub. Date: Nov. 29, 2007

(54) Apparatus for low-temperature plasma treatment

(75) Inventors: Shigehiro Hoshida, Ibaraki-ken (JP); Shinji Suzuki, Ibaraki-ken (JP); Tadashi Amano, Ibaraki-ken (JP)

Correspondence Address: MILLEN, WHITE, ZELANO & BRANIGAN, P.C., 2200 CLARENDON BLVD., SUITE 1400, ARLINGTON, VA, 22201, US

(73) Assignee: Shin-Etsu Chemical Co, Ltd

(21) Appl. No.: 11/802,384

(22) Filed: May 22, 2007

(30) Foreign Application Priority Data
May 23, 2006 (JP) 2006-143391

(51) Int. Cl. C23C 16/00

(52) U.S. Cl. 118/718

(57) ABSTRACT

An apparatus for low-temperature plasma treatment of a continuous length plastic film which can work for surface modifying processing for a film using low-temperature plasma while maintaining the dimensional stability without causing damage to the film. The apparatus for performing surface modifying processing for a film comprises: a first vacuum chamber equipped with an unrolling unit for unrolling a rolled plastic film; a second vacuum chamber in which the unrolled plastic film is subjected to a low-temperature plasma treatment on the surface; and a third vacuum chamber equipped with a winding unit for winding the plasma-treated plastic film into a roll, the vacuum chambers being connected together in series along the running direction of the plastic film under treatment.

### BACKGROUND OF THE INVENTION

1. Field of the Invention

The present invention relates to an apparatus for low-temperature plasma treatment for modification of the surface properties of various types of plastic films (hereinafter simply referred to as films).

2. Description of the Related Art

It is widely known heretofore that, by low-temperature plasma treatment of a film surface, the wettability of the surface can be improved, the coatability behavior for adhesives or the like can be improved, and adhesion between the film and an adhesive can be enhanced.

Usually, film is manufactured by continuous type equipment, and is wound up into a roll, so that surface treatment of a rolled film using low-temperature plasma is preferably conducted by a continuous type apparatus.

Therefore, surface treatment of a film using low-temperature plasma is performed as shown in FIG. 3 by a method of placing the plasma treatment apparatus inside a vacuum container 16, providing sealing rollers 17, 18 between an unrolling unit 2 and the vacuum chamber 16 and between the vacuum chamber 16 and a winding unit 5, inserting a film 1 into the vacuum chamber from the unrolling unit 2 through the sealing rollers 17, and after low-temperature plasma treatment inside the vacuum chamber, passing the film 1 through the sealing rollers 18 and winding on the winding unit 5 (Japanese Laid-open Patent Application S57-18737), or as shown in FIG. 4 by a method of placing both an unrolling unit 2 for film 1 and a winding unit 5 in addition to a plasma treatment apparatus comprising anode 14 and cathode 15 in a vacuum chamber 19 for a CVD equipment that forms a thin film on a film using continuous type equipment (Japanese Laid-open Patent Application H09-209158).

With an apparatus that uses a sealing apparatus as in Japanese Laid-open Patent Application S57-18737, the film passes through a plurality of pairs of sealing rollers so that a gap can form between the sealing rollers because of wear and degradation of the sealing rollers, and gases other than the process gas can penetrate into the apparatus, so that sealing is extremely difficult, the degree of vacuum in the vacuum chamber will be insufficient, and there will be problems such that the low temperature plasma treatment will be insufficient.

Furthermore, the film is intervening between the opposite sealing rollers, so that a heavy load may be applied to the film during unrolling because of wear or degradation of the sealing rollers, the dimensional stability of the film will be degraded, and the film may be damaged or scratched.

The method of Japanese Laid-open Patent Application H09-209158 places the unrolling unit and the winding unit inside a single vacuum chamber, so that there are no problems with respect to insufficient sealing effect because of the sealing rollers as in Japanese Laid-open Patent Application S57-18737, but because the drive mechanism is placed in the same vacuum chamber, there can be problems with the drive mechanism being damaged by the plasma or problems due to corrosion of the metal by the gases activated with the plasma.

### SUMMARY OF THE INVENTION

Therefore, an object of the present invention is to solve the problems of the aforementioned conventional technology and to provide an apparatus for low-temperature plasma treatment of continuous length film which can treat the surface of a film using low temperature plasma while maintaining dimensional stability without causing damage to the film.

The apparatus for low-temperature plasma treatment according to the present invention is an apparatus for treating the surface of a plastic film, comprising: (1) a first vacuum chamber equipped with an unrolling unit for unrolling a rolled plastic film; (2) a second vacuum chamber in which the unrolled plastic film is subjected to a low-temperature plasma treatment on the surface; and (3) a third vacuum chamber equipped with a winding unit for winding the plasma-treated plastic film into a roll, the vacuum chambers (1) to (3) is connected together in series along the running direction of the plastic film under treatment.

The vacuum chambers are preferably connected at a joining part therebetween, through which the plastic film under treatment runs, the clearances between the upper and lower surfaces of the running plastic film and the upper and lower lips of the joining part, respectively, each having a thickness not exceeding 300 mm. The second vacuum chamber is preferably equipped with a cathode which is of the drum-formed type having a water-cooling means.

Furthermore, the vacuum chambers are preferably formed of a stainless steel or aluminum, but forming of a common steel is also possible, in which case the inner surface should be coated with a resinous coating or a stainless steel layer formed by flame spraying.

The apparatus for low-temperature plasma treatment of the present invention does not use sealing rollers as with the conventional technology, so that damages or contamination of the film by the sealing rollers can be avoided, and the pressure of vacuum in the vacuum chamber can be kept stabilized, so that the surface treatment of the film can be uniform.

With the apparatus of the present invention, the equipment is not damaged by plasma or activated gas, so the operation can be performed uniformly for a long period of time, and the maintenance costs of the equipment can be minimized.

### BRIEF DESCRIPTION OF THE DRAWINGS

FIG. 1 is a schematic longitudinal cross section diagram showing the low-temperature plasma treatment apparatus used in Example 1;

FIG. 2 is a schematic longitudinal cross section diagram showing the low-temperature-plasma treatment apparatus used in Example 4;

FIG. 3 is a schematic longitudinal cross section diagram showing a conventional low temperature-plasma treatment apparatus used in Comparative Example 1; and

FIG. 4 is a schematic longitudinal cross section diagram showing a conventional low-temperature-plasma treatment apparatus used in Comparative Example 2.

### DESCRIPTION OF THE PREFERRED EMBODIMENTS

The apparatus for low-temperature plasma treatment according to the present invention will be described below in further detail using the drawings.

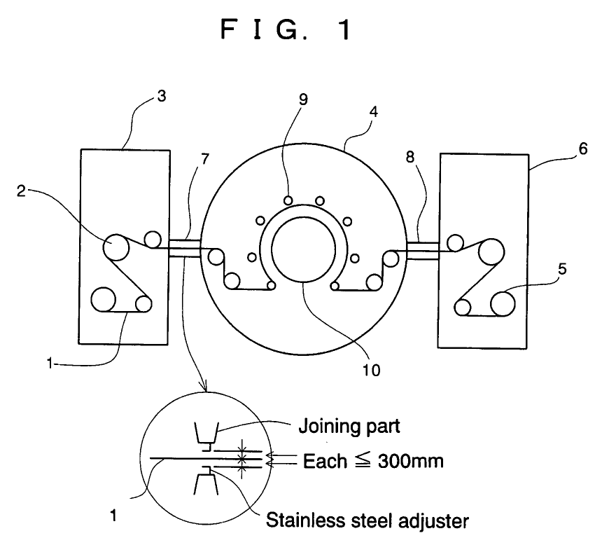

FIG. 1 is a schematic vertical cross section diagram showing an example of an apparatus for low temperature-plasma treatment according to the present invention.

The apparatus for surface treatment of a film according to the present invention comprises a first vacuum chamber 3 equipped with an unrolling unit 2 for continuously unrolling a rolled film 1, a second vacuum chamber 4 in which low-temperature plasma treatment is performed; and a third vacuum chamber 6 equipped with a winding unit 5 for continuously winding the plasma treated film 1, with the vacuum chambers 3, 4, 6 being mutually connected through the joining parts 7, 8.

The unrolling unit 2 and the winding unit 5 are placed in the first vacuum chamber 3 and the third vacuum chamber 6, respectively, but there are no particular limitations thereto so that any apparatuses capable of unrolling a film or capable of winding up a film can serve here for the purpose.

The unrolling unit 2 and the winding unit 5 may be any apparatus usually under use for paper tube making or plastic tube making or the like, and the unrolling and winding diameter may be a standard 3-inches or 6-inches or thereabout.

Note that various devices which are usually used for film 1, for instance as a tension controller for controlling the tension on the film 1 or a film edge limiter for restricting the rolling of the film 1, may also be provided when necessary.

Anodes 9 connected to a high-frequency power source and a cathode 10 which acts as the ground are placed in the second vacuum chamber 4 as the apparatus for plasma treatment. The anode 9 and the cathode 10 are not particularly limitative, so long as they are capable of generating plasma. However, the shape of the anode 9 may be a standard flat plate, but a rod forms are preferable because better plasma treatment effect can be achieved. Similarly, the shape of the cathode 10 may be a standard flat plate, but a rotating drum shape is preferable from the viewpoint of continuously treating the film 1. The reason for this is that the film 1 can be continuously treated while rotating the drum without the film 1 rubbing on the surface of the drum. Note, the film 1 is heated by the plasma treatment, but the cathode 10 has a drum form, so a water-cooled form with water cooling from the inside is simple.

The first, second, and third vacuum chambers of the present invention must be connected together, and the joining parts preferably have a construction such that the plasma generated in the second vacuum chamber does not diffuse out into the first and third vacuum chambers. The reason is that if plasma flows into the first and third vacuum chambers, regions which are not to be treated will be treated, and the plasma treatment effect will not be uniform. Therefore, the clearance in both of the joining parts that the running film passes through is preferably as small as possible, and as shown by the enlargement of the joining parts in FIG. 1, if the clearance is no greater than 300 mm from the film surface in both the upward and downward directions, penetration of the plasma into the first and third vacuum chambers can essentially be prevented. Furthermore, for the same reasons, the diffusing-out of plasma can be controlled by placing magnets in the joining parts.

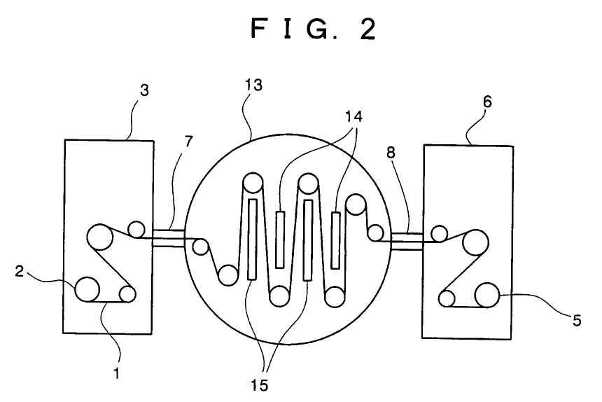

FIG. 2 is a schematic vertical cross section diagram showing another embodiment of the apparatus for low-temperature plasma treatment according to the present invention, wherein flat-plate anodes 14 and similar flat-plate cathodes 15 are placed in the second vacuum chamber 13. The first and third vacuum chambers 3, 6 are the same as in the embodiment of FIG. 1, and are connected to the second vacuum chamber 13 by joining parts 7, 8 respectively.

The first, second, and third vacuum chambers of the present invention as well as the construction thereof are not particularly li,itative, but should be able to maintain a vacuum pressure that can provide an environment where low-temperature plasma can easily be generated, and that unrolling and winding can be performed.

The material of the vacuum chambers is preferably constructed such that iron is not exposed on the inside surface of the vacuum chamber because the surface of iron is subject to corrosioned by plasma emission if so-called common steel is exposed on the inside surface of the vacuum chamber. Therefore the vacuum chamber housing is preferably made of stainless steel or aluminum. However, if the vacuum chamber housing is made from solid stainless steel or aluminum, the cost will be so high that it is also acceptable to make the vacuum chamber housing from common steel and to coat the inner surface with a plastic resin or the like. Note, the resin coating may be degraded if continuedly exposed to plasma atmosphere. Therefore, from the balance between cost and corrosion resistance, the vacuum chamber housing may be built from iron with flame spray coating by using a stainless steel on the inside surface.

Low temperature plasma treatment is a widely known process simply referred to as a plasma treatment, and is the same treatment disclosed in the aforementioned Japanese Laid-open Patent Applications S57-18737 and H09-209158, as well as in standard technical books (for instance “Surface Treatment of Polymer Materials Using Plasma, Industrial Materials, Vol. 32, No. 3, pages 24-30, 1984” or “Surface Treatment of Polymer Materials Using Low Temperature Plasma, Polymer Digest, Vol. 35, No. 5, pages 2-16, 1983” and elsewhere.

Note, the plasma treatment of the present invention differs from so-called normal pressure plasma treatment and is performed in vacuum. For example, a pressure of vacuum of 100 Pa or lower is preferable for stable plasma treatment. A pressure of vacuum of 30 Pa or lower is even more preferable.

Furthermore, the frequency of the high-frequency power source is not particularly limitative, and usually a range between 10 kHz and 14 MHz may be used.

The surrounding gas for low temperature plasma generation may be selected from gases exhibiting high etching effect such as nitrogen, oxygen, and argon and the gases having polymerizability as employed in the so-called CVD process.

The films suitable to the treatment in the present invention can be a standard commercial film. Examples include polyethylene films, polypropylene films, polyvinylchloride films, polyimide films, liquid crystal polymer films, polyester films, fluorocarbon polymer films, polyamide films, cellulose films, and aramid films and the like. Of these, polyester films commercially sold as Lumirror, Tetoron, and Diafoil, polyimide film commercially sold as Kapton, Apical, and Upilex, and aramid films commercially sold as Mictron and Aramica are particularly suitable.

With the present invention, the thickness of the film for treatment is not particularly limitative, but, since the film is unrolled from a rolled form and wound up into a rolled form on a continuous type apparatus, the thickness is preferably between 2 microns and 500 microns. A thickness between 2 microns and 300 microns is more preferable.

By using the apparatus of the present invention, a continuous-length film can be treated with low temperature plasma without the unrolling unit and winding unit being damaged by the plasma.

### EXAMPLES

Next, the present invention is described in more details by way of examples and comparative examples, but the present invention is never limited by and to these examples.

### Example 1

A device having the structure shown in FIG. 1 was used. The vacuum chambers were formed of a stainless steel. A 12 micron thick PET film (product name: Lumirror manufactured by Toray) was unrolled from the unrolling unit and passed through the plasma treatment apparatus (manufactured by Shin-Etsu Engineering Co.) and a winding unit, with the PET film passing through the slit at the joining part between the first vacuum chamber and the second vacuum chamber and the slit at the joining part between the second vacuum chamber and the third vacuum chamber. The slit width was adjusted by using a stainless steel sheet so as to have a clearances above and below the PET film surfaces were each 290 mm.

After setting of the PET film, the vacuum chambers were closed and evacuation of the chambers was started. When the pressure of vacuum had reached 2 Pa, nitrogen gas was introduced into the second vacuum chamber at a rate of 1 liter/minute, and the pressure in the chambers was stationarilyly maintained at 10 Pa.

Furthermore, the unrolling speed of the PET film was 10 m/minute, and the low-temperature plasma treatment was undertaken using a high frequency power source (produced by Kokusai Electric Co.) with a load of 350 watts at 300 KHz.

### Example 2

By using an apparatus illustrated in FIG. 1, low-temperature plasma treatment was undertaken in the same manner as in Example 1, except that the iron-made vacuum chambers were flame spray coated with SUS304 stainless steel on the inside surfaces.

### Example 3

By using the apparatus illustrated in FIG. 1, low-temperature plasma treatment was undertaken in the same manner as in Example 1, except that the material of the vacuum chambers was changed from stainless steel to common steel, and the film for the treatment was changed to a 25 micron-thick PI film (product name: Apical, produced by Kaneka Co.).

### Example 4

By using the apparatus illustrated in FIG. 1, low-temperature plasma treatment was undertaken in the same manner as in Example 1, except that the material of the vacuum chambers was a common steel coated on the inside surface with an epoxy resin, and the film for the treatment was changed to a 25 micron thick PI film (polyimide film) (product name: Apical, produced by Kaneka Co.).

### Example 5

By using the apparatus illustrated in FIG. 1, low-temperature plasma treatment was undertaken in the same manner as in Example 1, except that the clearances of both joining parts in both the up and down directions were adjusted with stainless steel sheets to be 320 mm, a 25 micron PI film (product name: Apical, produced by Kaneka Co.) was used, and the surrounding gas was oxygen instead of nitrogen.

### Example 6

An apparatus having the structure illustrated in FIG. 2 was used. The vacuum chambers were built from common steel and flame-spray coated with SUS 304 stainless steel on the inside surfaces. A 12 micron thick PET film (product name: Lumirror manufactured by Toray) was unrolled from the unrolling unit, and introduced to the plasma treatment apparatus (manufactured by Shin-Etsu Engineering Co.) and the winding unit, the PET film was passed through the slit having a clearance of the joining part between the first vacuum chamber and the second vacuum chamber and the joining part between the second vacuum chamber and the third vacuum chamber, and the clearances above and below the PET film surfaces were adjusted to be 290 mm using stainless steel sheets.

After setting of the PET film, the vacuum chambers were closed and evacuation was started, and when the pressure of vacuum had reached 2 Pa, nitrogen gas was introduced into the second vacuum chamber at a rate of 1 liter/minute, and the pressure in the chamber was stationarily maintained at 10 Pa.

Furthermore, the unrolling speed of the PET film was set at 10 meters/minute, and the low-temperature plasma treatment was performed using a high-frequency power source (produced by Kokusai Electric) with a load of 350 watts at 300 kHz.

### Comparative Example 1

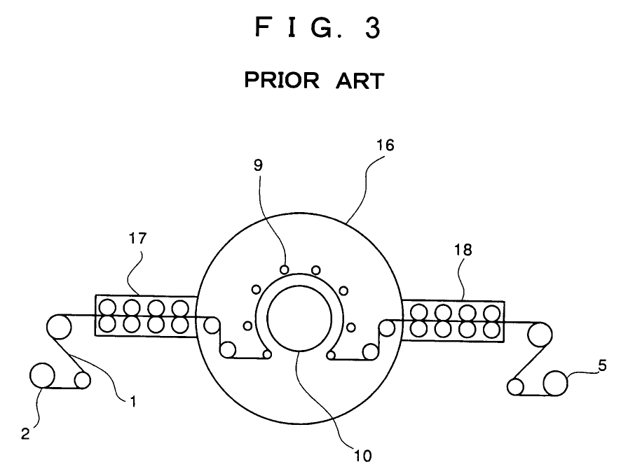

A plasma treatment apparatus (manufactured by Hitachi Ltd.) having the structure illustrated in FIG. 3 was used. After a 12 micron thick PET film (product name: Lumirror produced by Toray) was unrolled from the unrolling unit and passed between the sealing rollers to the center plasma treatment apparatus body, the vacuum chamber was closed, and when a vacuum pressure had reached 2 Pa, nitrogen gas was introduced into the vacuum chamber at a rate of 1 liter/minute, and the pressure in the vacuum chamber was stably maintained at a vacuum of 10 Pa. Furthermore, the PET film was introduced at a speed of 10 m/min, and the low-temperature plasma treatment was performed using a high frequency power source (produced by Kokusai Electric Co.) at a load of 350 watts and 300 kHz.

### Comparative Example 2

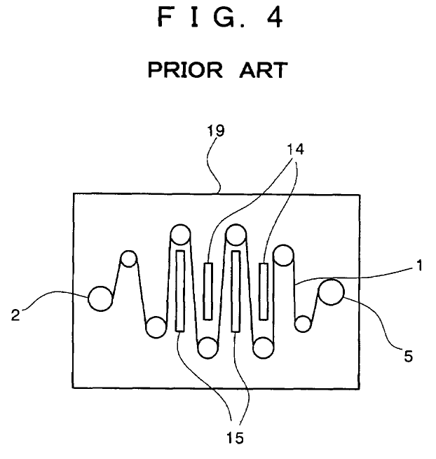

A plasma processing apparatus (manufactured by Shin-Etsu Engineering Co. having the structure illustrated in FIG. 4 was used. After a 12 micron PET film (product name: Lumirror produced by Toray) was unrolled from the unrolling unit and passed to the center plasma treatment apparatus body, the vacuum chamber was closed, and when the vacuum pressure had reached 2 Pa, nitrogen gas was introduced into the vacuum chamber at a rate of 1 liter/minute, and the pressure in the vacuum chamber was stably maintained at a pressure of 10 Pa. Furthermore, the PET film was fed at a speed of 10 meters/minute, and the low-temperature plasma treatment was performed using a high-frequency power source (produced by Kokusai Electric Co.) at a load of 350 watts and 300 kHz.

The following measurements and observations were undertaken for Examples 1 through 6 and Comparative Examples 1 and 2, and the results are summarized and shown in Table 1. Note, the evaluation criterion for each of the evaluation items was as shown below.

(1) Contact angle (degrees): The angle of contact between the surface of a plasma treated film and a liquid droplet was measured using a contact angle measuring apparatus produced by Kyowa Science.

(2) Film wrinkles: The plasma treated film was visually inspected for wrinkles.

Wrinkles not found: grade A

Wrinkles found: grade B

(3) Vacuum chamber cost: Comparison was made between the cost paid for the base materials required for construction of the vacuum chamber.

Relatively low cost: grade A

Slightly lower cost: grade B

Relatively high cost: grade C

(4) Thermal degradation of films: A 100 mm by 100 mm piece of the film taken by cutting the film before or immediately after the treatment was laid flat on a horizontal board to conduct measurement of the highest lift of the film piece. An average of five measurements was taken as the lift value which was assumed to correspond to the extent of thermal degradation of the film. The lift value of the films before the plasma treatment was 1.0 mm for the PET film and 1.3 mm for the PI film.

Lift value of 2 mm or smaller, grade A

Lift value of 2 mm to 4 mm grade B

Lift value of 4 mm or larger grade C: O

(5) Corrosion of vacuum chamber walls: the surface condition of the inside surface of the vacuum chambers was visually inspected after 300 hours of continued low-temperature plasma discharge without loading of the plastic film roll.

Just as before: grade A

Resin-coated surface roughened with partial falling of the coating: grade B

Rusting found on a part of the inner surface: grade C

(6) Stability of low-temperature plasma discharge. When the low-temperature discharge is unstable or irregular, plasma emission is noted in the first and third vacuum chambers under the operating conditions of Examples and Comparative Examples resulting in a decreased plasma treatment efficiency.

No plasma discharge in the first and third vacuum chambers: grade A:

Plasma discharge in the first and third vacuum chambers: grade B

TABLE 1

| | | | | | | | Comparative | Comparative |
|---|---|---|---|---|---|---|---|---|
| | Example 1 | Example 2 | Example 3 | Example 4 | Example 5 | Example 6 | Example 1 | Example 2 |
| cathode | drum-formed | drum-formed | drum-formed | drum-formed | drum-formed | plate-formed | drum-formed | plate-formed |
| anode | rod-formed | rod-formed | rod-formed | rod-formed | rod-formed | plate-formed | rod-formed | plate-formed |
| joining part, | 290/290 | 290/290 | 290/290 | 290/290 | 320/320 | 290/290 | sealing rollers | — |
| upper/lower | stainless | common | common | common | stainless | common | common | aluminum |
| chearance, mm | steel | steel | steel | steel | steel | steel | steel | — |
| vacuum chamber | — | flame- | | resin coating | — | flame- | — | |
| material | | sprayed | | | | sprayed | | |
| coating | | | | | | | | |
| vacuum pressure, Pa | 10 | 10 | 10 | 10 | 10 | 10 | 10 | 10 |
| gas | nitrogen | nitrogen | nitrogen | nitrogen | oxygen | nitrogen | nitrogen | nitrogen |
| plastic film treated | PET | PET | PI | PI | PI | PET | PET | PET |
| contact angle, | 10 | 10 | 12 | 12 | 11 | 14 | 11 | 11 |
| degrees | | | | | | | | |
| wrinkles | A | A | A | A | A | A | B | A |
| cost of vacuum | C | B | A | A | C | B | A | C |
| chambers | | | | | | | | |
| thermal degradation | A | A | A | A | A | B | A | B |
| corrosion | A | A | C | B | A | A | C | A |
| irregular plasma | A | A | A | A | B | A | A | B |
| discharge | | | | | | | | |

The present invention will contribute to reduced manufacturing costs for a low temperature plasma treatment apparatus and to reduced surface treatment costs for the film.

What is claimed is:

1. An apparatus for low-temperature plasma treatment of a plastic film surface which comprises:
(1) a first vacuum chamber equipped with an unrolling unit for unrolling a rolled plastic film;
(2) a second vacuum chamber in which the unrolled plastic film is subjected to a low-temperature plasma treatment on the surface; and
(3) a third vacuum chamber equipped with a winding unit for winding the plasma-treated plastic film into a roll, the vacuum chambers (1) to (3) being connected together in series along the running direction of the plastic film under treatment.

2. The apparatus according to claim 1 wherein the adjacent vacuum chambers are connected at a joining part therebetween, through which the plastic film under treatment runs, the clearances between the upper and lower surfaces of the running plastic film and the upper and lower lips of the joining part, respectively, each having a thickness not exceeding 300 mm.

3. The apparatus according to claim 1 wherein the second vacuum chamber is equipped with a cathode which is of the drum-formed type having a water-cooling means.

4. The apparatus according to claim 1 wherein each of the vacuum chambers is formed of a stainless steel or aluminum.

5. The apparatus according to claim 1 wherein each of the vacuum chambers is formed of iron and coated on the inner surface with a resinous coating composition.

6. The apparatus according to claim 1 wherein each of the vacuum chambers is formed of iron and coated on the inner surface with a stainless steel layer formed by flame spraying.
